(19) United States
(12) Patent Application Publication
(10) Pub. No.: US 2004/0229477 A1
(43) Pub. Date: Nov. 18, 2004

(54) Apparatus and method for producing a <111> orientation aluminum film for an integrated circuit device

(76) Inventors: Timothy J. Daniel, Orlando, FL (US); Joseph W. Buckfeller, Windermere, FL (US); Craig C. Clabough, Cocoa Beach, FL (US); Catherine Vartuli, Savannah, GA (US)

Correspondence Address: BEUSSE BROWNLEE WOLTER MORA & MAIRE, P. A., 390 NORTH ORANGE AVENUE, SUITE 2500, ORLANDO, FL, 32801, US

(21) Appl. No.: 10/615,583

(22) Filed: Jul. 8, 2003

Related U.S. Application Data
(60) Provisional application No. 60/470,120, filed on May 13, 2003.

(51) Int. Cl. H01L 21/42

(52) U.S. Cl. 438/795

(57) ABSTRACT

A method and apparatus for depositing material from a target onto a semiconductor wafer. The wafer is positioned above a chuck that is heated by a chuck heater. Radiant heat flow from the chuck to the wafer is the primary heat source for the wafer. Thus by controlling the chuck heater temperature the wafer temperature can be maintained within a desired range to effectuate desired characteristics in the deposited material.

This application claims the benefit of provisional patent application Ser. No. 60/470,120 filed on May 13, 2003.

### FIELD OF THE INVENTION

This invention relates generally to the formation of aluminum metallization layers for an integrated circuit device, and more specifically to the formation of an aluminum metallization layer having a substantially <111> aluminum grain orientation.

### BACKGROUND OF THE INVENTION

Integrated circuit devices (or chips) typically comprise a silicon substrate and semiconductor elements, such as transistors, formed from doped regions within the substrate. Interconnect structures, formed in parallel layers overlying the semiconductor substrate, provide electrical connection between semiconductor elements to form electrical circuits. Typically, several (e.g., 6-9) interconnect layers (each referred to as an “M” or metallization layer) are required to interconnect the doped regions and elements in an integrated circuit device. The top metallization layer provides attachment points for conductive interconnects (e.g., bond wires) that connect the device circuit's off-chip, such as to pins or leads of a package structure.

Each interconnect structure comprises a plurality of substantially horizontal conductive interconnect lines or leads and a plurality of conductive vertical vias or plugs. The first or lowest level of conductive vias interconnects an underlying semiconductor element to an overlying interconnect line. Upper level vias connect an underlying and an overlying interconnect line. The interconnect structures are formed by employing conventional metal deposition, photolithographic masking, patterning and etching techniques. One material conventionally used for the horizontal conductive interconnect layers comprises aluminum. To form the interconnect lines the aluminum is blanket deposited over an intermetallic dielectric layer disposed on an upper surface of the substrate, then patterned according to conventional techniques to form the desired interconnect lines. The material of the conductive vias conventionally comprises tungsten.

Sputtering, also known as physical vapor deposition (PVD), is one known technique for blanket depositing aluminum on the intermetallic dielectric layer. One example of a prior art sputtering process chamber 100 is illustrated in FIG. 1, in which the components are illustrated in the wafer load position, i.e., when the wafer is loaded into the chamber. The chamber 100, which is maintained at a vacuum, encloses a target 102 formed from a material to be deposited on a wafer 106 located near the bottom of the chamber 100. The target 102 is negatively biased with respect to a chamber shield 108 (which is typically grounded) by a direct current power supply 110. Conventionally, argon molecules are introduced into the chamber 100 via an inlet 112 and ionized by the electric field between the target 102 and the chamber shield 108 (i.e., ground) to produce a plasma of positively charged argon ions 116. The argon ions 116 gain momentum as they accelerate toward the negatively charged target 102.

A magnet 118 creates a magnetic field that generally confines the argon plasma to a region 117, where the increased plasma density improves the sputtering efficiency. As the argon ions 116 bombard the target 102, the momentum of the ions is transferred to the molecules or atoms of the target material, sputtering or knocking these molecules or atoms from the target 102. A high density of argon ions 116 in the chamber 100 ensures that a significant number of the sputtered atoms condense on an upper surface of the wafer 106. The target material, in the case of aluminum, is deposited on the wafer 106 without undergoing any chemical or compositional changes. The various sputtering process parameters, including chamber pressure, temperature and deposition power (i.e., the amount of power (the product of voltage and current) supplied to the target 102 by the power supply 110) can be varied to achieve the desired characteristics in the sputtered film. Generally, a higher target power increases the target deposition rate.

Prior to initiating the deposition process, a robot arm (not shown in FIG. 1) transports the wafer 106 into the chamber 100 and positions the wafer 106 on a plurality of wafer lift pins 124. As a chuck 126 is driven upwardly, retracting the pins 124 into the chuck 126, the wafer 106 comes to rest on pads 127 of a pedestal cover 128 overlying an upper surface 129 of the chuck 126.

As the chuck 126 continues moving upwardly, the wafer 106 contacts a clamp assembly 130 (a ring-like structure) supported by a wafer/clamp alignment tube assembly 132. The chuck 126 continues the upward motion until the clamp 130, the wafer 106, and the chuck 126 are in the process position illustrated in FIG. 2. The deposition process is then initiated. During the sputtering process the force exerted between the clamp and the chuck 126 holds the wafer 106 in place against the pads 127. This final process position is referred to as the source to substrate spacing, where the target 102 is the source and the wafer 106 is the substrate. The spacing is determined to provide the optimum deposition uniformity during the sputtering process.

When the deposition process has ended, the above steps are executed in reverse order to remove the wafer 106 from the chamber 100. The robot arm transfers the wafer to the next chamber for execution of the next process step.

As is known, the clamp 130 is a ring-like structure that contacts only the wafer periphery. In one embodiment, the wafer diameter is about 200 mm with a peripheral edge exclusion area 140 (see FIG. 3) of about 3 mm in which no semiconductor devices are fabricated. The clamp 130 contacts the wafer 106 at a contact point 141 within about 1 mm of the wafer bevel edge 142. However, a clamp region 143 extending beyond the contact point 141 shadows the wafer 106. Thus the edge exclusion area 140 comprises a peripheral ring region about 3 mm wide, which reduces the active wafer area.

During aluminum sputtering on the surface of the wafer 106, an aluminum deposit 144 is formed on an upper surface 145 of the clamp 130, producing an additional shadowing effect on the wafer 106. This shadowing effect can extend beyond the 3 mm edge exclusion area 140.

As the deposition of aluminum on the upper surface 145 continues during deposition processing in the chamber 108, eventually the aluminum deposit 144 can contact an upper surface 146 of the wafer 106 at a contact point 147 as illustrated in FIG. 4. At the contact point 147 a weld-like effect is created between the wafer 106 and the clamp 130. When this occurs, the wafer 106 may not separable from the clamp 130 after the aluminum deposition process is completed.

Use of the clamp 130 can also cause the formation of defect particulates on the wafer 106. Returning to FIG. 1, the wafer/clamp alignment tube assembly 132 is adjustable to align the clamp 130 relative to the wafer 106. But the metal-to-metal contact between the clamp 130 and the wafer/clamp alignment tube assembly 132 is a generating source for particles that can fall onto the upper surface 146, creating potential wafer defects and reducing the process yield.

An electrostatic chuck is known to overcome certain disadvantages associated with use of the clamp 130. An electrostatic chuck holds the wafer 106 in a stable, spaced-apart position by an electrostatic force generated by an electric field formed between the wafer 106 and the chuck. It is known, however, that this electric field can detrimentally affect the material deposition process by generating backside particles during the de-chucking process, i.e., removing the wafer 106 from the chamber 100. There is also a measurable thermal gradient across the electrostatic chuck resulting in aluminum grain variations across the wafer 106. In particular, increased levels of backside particles and changes in the grain orientation have been observed, especially near the wafer center. Electrostatic chucks are considerably more expensive than the wafer clamp system and have a shorter useful life.

In both the clamped and electrostatic chucks, embedded heaters heat the chuck to a predetermined temperature (e.g., about 300° C.) to maintain a desired wafer temperature. In both chuck types, a gas (usually argon) flows behind the wafer 106 to thermally couple the chuck 126 and the wafer 106 for to maintain the wafer temperature at the chuck temperature. The gas is introduced to the wafer backside through an orifice 149 in the chuck 126. See FIGS. 1 and 2. Since the frictional forces of the impinging sputtered atoms can raise the wafer temperature above the chuck temperature, the gas (referred to as backside cooling) cools the wafer 106 as it flows between the wafer 106 and the chuck 126. Wit heat transfer from the gas, the chuck may also serve as a heat sink. The backside cooling gas is withdrawn from the chamber 108 by a cryogenic pump (not shown in the Figures) operable to maintain the chamber vacuum. If the backside cooling gas is not evenly distributed across the wafer bottom surface, hot spots and attendant aluminum defects can appear in the deposited layer. It has been observed that without backside cooling the wafer temperature increases with time, approaching the plasma temperature. Such excessive wafer temperatures can cause defects in the deposited aluminum and also destroy the wafer. Thus it is known that controlling the chuck temperature during the deposition process, together with the use of backside cooling (and a clamp in the clamp-type chucks) provides control over the wafer temperature to improve the material deposition process.

Electromigration is a known problem for aluminum interconnect leads in integrated circuit devices. The current carried by the long, thin aluminum leads produces an electric field in the lead that decreases in magnitude from the input side to the output side. Also, heat generated by current flow within the lead establishes a thermal gradient. The aluminum atoms in the conductor become mobile and diffuse within the conductor in the direction of the two gradients. The first observed effect is conductor thinning, and in the extreme case the conductor develops an open circuit and the device ceases to function.

It is known that use of aluminum alloys, including alloys of copper, silicon and aluminum, can reduce electromigration effects. However, these aluminum alloys present increased complexity for the deposition equipment and processes, and exhibit different etch rates than pure aluminum, necessitating process modifications to achieve the desired etch results. Compared with pure aluminum, the alloys may exhibit increased film resistivity and thus increased lead resistance.

The interconnect leads in an integrated circuit device are also under considerable mechanical stress due to thermally induced expansion and contraction during operation. These effects contribute to stress voiding failure mechanisms in which the interconnect metal separates, creating a void.

It has been shown that the aluminum grain orientation and grain size affect the electromigration and stress voiding characteristics of an aluminum interconnect lead. In particular, an aluminum grain orientation along the <111>plane is known to produce minimal electromigration effects. According to the prior art, when aluminum is deposited over a titanium/titanium nitride stack which is a typical stack composition, the aluminum grain orientation is controlled by the underlying titanium orientation. The titanium-nitride orientation is also controlled by the titanium orientation. Thus if the titanium orientation is correct (i.e., <002>) the overlying aluminum will have a high probability of exhibiting a <111> orientation. According to the prior art, the wafer temperature affects only the aluminum grain size, not the grain orientation.

### BRIEF SUMMARY OF THE INVENTION

The present invention teaches a method for depositing material on a semiconductor wafer, wherein the wafer temperature is maintained within a desired temperature range. The method comprises providing a target of the material to be deposited. The wafer is supported on a chuck and positioned between the target and the chuck at distance from the target wherein the chuck temperature substantially determines the wafer temperature. Target material is deposited on the wafer in response to particles impinging the target. The chuck temperature is controlled to maintain the wafer temperature within the desired temperature range during the deposition process.

The invention further comprises a physical vapor deposition chamber for depositing material on a wafer, wherein the wafer temperature is maintained within a predetermined temperature range. The chamber comprises a target formed from the material to be deposited on the wafer and a chuck for supporting the wafer. A controller controls a chuck heater to heat the wafer to a temperature within the predetermined temperature range.

### BRIEF DESCRIPTION OF THE DRAWINGS

The foregoing and other features of the present invention will be apparent from the following more particular description of the invention as illustrated in the accompanying drawings, in which like reference characters refer to the same parts throughout the different figures. The drawings are not necessarily to scale, emphasis instead being placed upon illustrating the principles of the invention.

FIGS. 1 and 2 illustrate prior art physical vapor deposition chambers.

FIGS. 3 and 4 illustrate the contact between prior art wafer clamps and wafer.

FIGS. 5 and 6 illustrate a physical vapor deposition chamber according to the teachings of one embodiment of the present invention.

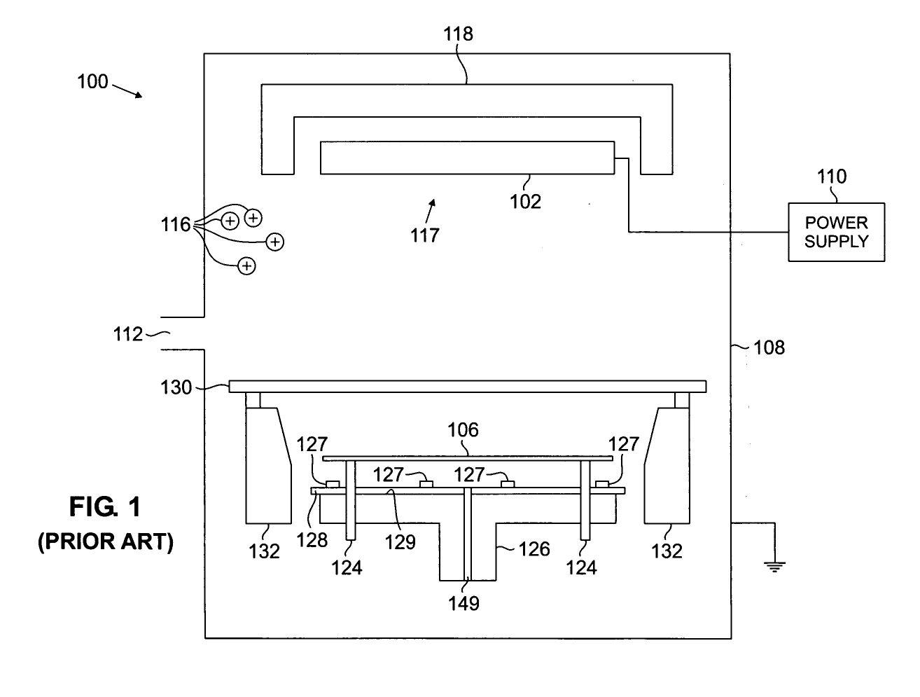

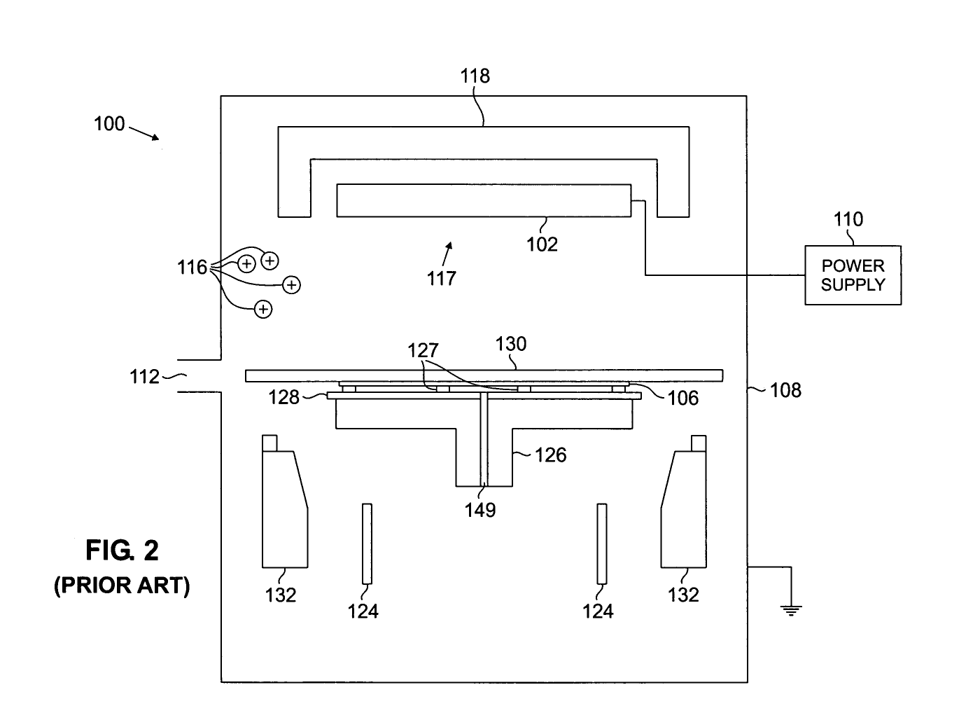

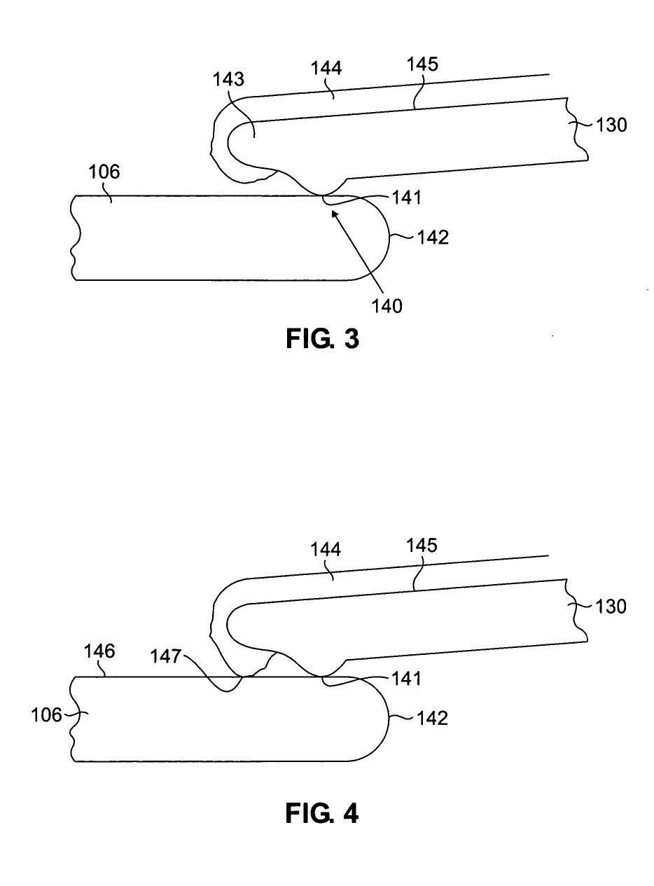

### DETAILED DESCRIPTION OF THE INVENTION

Before describing in detail the particular optimized sputtering process in accordance with the present invention, it should be observed that the present invention resides in a novel and non-obvious combination of elements and process steps. Accordingly, the elements have been represented by conventional elements in the drawings, showing only those specific details that are pertinent to the present invention so as not to obscure the disclosure with details that will be readily apparent to those skilled in the art having the benefit of the description herein.

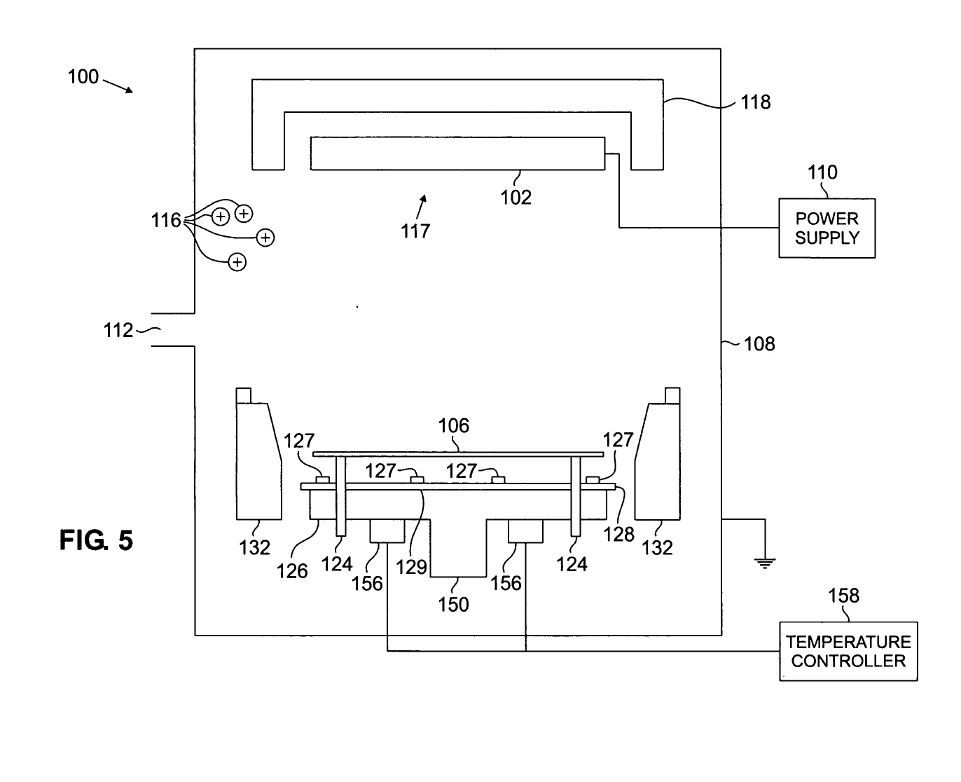

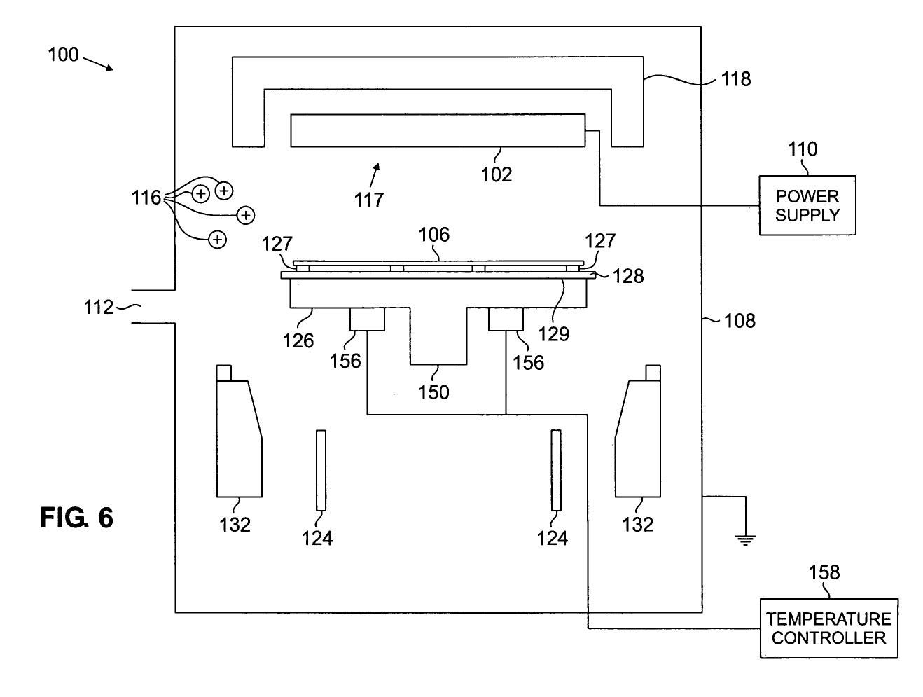

FIG. 5 illustrates a clampless chuck 150 for use in a physical vapor deposition chamber according to one embodiment of the present invention. In FIG. 5 the elements are illustrated in the wafer load position. FIG. 6 illustrates the same elements in the deposition process position. The wafer weight exerts a downwardly directed force that holds the wafer 106 against the pads 127 of the pedestal cover 128. Wafer backside cooling is not required according to the teachings of the present invention. Thus absent backside cooling, there is no coolant fluid force directed against the bottom surface of the wafer 106 and no need for an additional downward force, such as by use of a clamp, to overcome the coolant fluid force. Advantageously, avoiding use of a clamp permits semiconductor devices to be fabricated in the wafer edge exclusion area 140 that is obscured by the prior art clamp 130.

According to the present invention, it has been determined that the wafer temperature affects both aluminum grain size and grain orientation. The underlying material layer should be in a predetermined orientation so that the sputtered aluminum grows in the preferred orientation. Although the influence of wafer temperature on grain orientation may not be as significant as the orientation of the underlying layer (titanium for example), the number of aluminum atoms exhibiting a <111> crystal orientation increases when the wafer is maintained within a predetermined temperature range. Maintaining the desired wafer temperature provides the thermal characteristics required for proper growth of the aluminum material layer. If the thermal properties of the deposition are not properly maintained, the aluminum alloy precipitates impurities to the aluminum grain boundaries, which will have a detrimental effect on the aluminum film growth. Such alterations in the aluminum film directly impact the orientation of the aluminum atoms.

It has further been determined that a wafer temperature of between about 245° C. and 285° C. produces an advantageous aluminum grain size (about 0.8 microns) with a substantial majority of the grains in the <111> crystal plane. According to the teachings of the present invention, the chuck temperature is controlled to achieve a wafer temperature in this range, taking into consideration the various chamber and process parameters that affect the chuck temperature, the wafer temperature, and the functional dependence between the wafer temperature and the chuck temperature.

To control the wafer temperature, the various uncontrolled process effects that influence the wafer temperature should be minimized. In the FIG. 6 configuration the wafer 106 is spaced apart from the target 102 such that at a distance of about 45 mm, the heat generated by the plasma and by the frictional forces of the impinging deposition particles are not dominant heat sources for the wafer 106. Instead, the wafer temperature is determined primarily by radiant heat flow from the chuck 150, as heated by chuck heaters 156 under control of a temperature controller 158. Because the wafer 106 is not in direct physical contact with the chuck 126, being separated therefrom by the height of the pads 127 on the pedestal cover 128 (typically, the pads 127 are about 2 mm in height) there is minimal conductive heat flow between the wafer 106 and the chuck 150.

It has been determined that a chuck temperature of between about 350° C. and 450° C. produces a wafer temperature of between about 245° C. and 285° C. At a chuck temperature of about 450° C. the wafer temperature of the present clampless process matches the temperature of the wafer in the prior art clamp processes, and the properties of the deposited film are substantially similar to those observed with the clamped chuck.

Although the chuck temperature is determined primarily by the controllable chuck heaters 156, the heat transfer between the chuck 126 and the wafer 106 is also influenced by certain characteristics of the PVD chamber 100. For example, the heat flow from the chuck 126 to the wafer 106 depends on the distance between the wafer 106 and the upper surface 129 of the chuck 126, i.e., the height of the pads 127 on the pedestal cover 128. The wafer temperature also depends on the duration of the deposition process, i.e., the time that the wafer 106 is subjected to the high-temperature deposition plasma and the frictional forces of the sputtered particles.

Additionally, in one embodiment the wafer temperature upon entering the PVD chamber 100 can be measured (using an optical pyrometer in one embodiment) and considered in establishing the chuck temperature. The entry temperature is dependent on the previous processes to which the wafer had been subjected, and the time required to transfer the wafer 106 from the previous chamber to the chamber 100. It is known that in certain processing tools the wafer temperature drops about 0.5° C./second while the wafer moves between tool chambers. Thus in one embodiment the chuck temperature, as controlled by the temperature controller 158, is also responsive to the initial wafer temperature, such that a wafer temperature of about 285° C. is maintained during the PVD process of the present invention.

In yet another embodiment, the wafer temperature is determined during the deposition process and the temperature value feedback to the temperature controller 158 for controlling the chuck heaters 156 in response thereto.

While the invention has been described with reference to preferred embodiments, it will be understood by those skilled in the art that various changes may be made and equivalent elements may be substituted for elements thereof without departing from the scope of the present invention. The scope of the present invention further includes any combination of the elements from the various embodiments set forth herein. In addition, modifications may be made to adapt a particular situation to the teachings of the present invention without departing from its essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method for depositing material on a semiconductor wafer, wherein the wafer temperature is maintained within a temperature range, the method comprising:
providing a target comprising the material to be deposited;
supporting the wafer on a chuck, wherein the wafer is positioned between the target and the chuck;
depositing material from the target on the wafer in response to particles impinging the target; and
controlling the wafer temperature within the temperature range by controlling the chuck temperature.

2. The method of claim 1 wherein the step of supporting the wafer further comprises supporting the wafer in a spaced apart relation from the chuck.

3. The method of claim 1 wherein the wafer is thermally coupled to the chuck by radiant heat flow.

4. The method of claim 3 wherein the wafer temperature is substantially determined by the radiant heat flow.

5. The method of claim 1 further comprising positioning the wafer at a distance from the target such that the chuck temperature substantially determines the wafer temperature.

6. The method of claim 1 wherein the material comprises aluminum or an aluminum alloy.

7. The method of claim 1 wherein the temperature range comprises temperatures between about 245° C. and 285° C.

8. The method of claim 1 wherein the step of controlling the wafer temperature comprises controlling the chuck temperature between about 350° C. and 450° C.

9. The method of claim 1 further comprising determining the wafer entry temperature prior to the step of depositing, wherein the step of controlling the wafer temperature further comprises controlling the chuck temperature in response to the wafer entry temperature.

10. The method of claim 1 wherein the step of depositing further comprises depositing material with a <111> crystal orientation on the wafer.

11. The method of claim 1 further comprising depositing an underlying layer on the wafer prior to depositing the material, wherein the underlying layer has a predetermined crystal orientation.

12. The method of claim 11 wherein the underlying layer comprises titanium having a <002> crystal orientation.

13. The method of claim 12 wherein the deposited material exhibits a desired grain orientation.

14. The method of claim 1 wherein the step of positioning the wafer further comprises positioning the wafer at a distance of about 45 mm from the target.

15. A physical vapor deposition chamber for depositing material on a wafer, wherein the wafer temperature is maintained within a temperature range, comprising:
a target formed from the material to be deposited on the wafer,
a chuck for supporting the wafer,
a chuck heater, and
a controller for controlling the chuck heater such that the wafer temperature is within the temperature range.

16. The physical vapor deposition chamber of claim 15 wherein the wafer is heated by radiant heat flow from the chuck to the wafer.

17. The physical vapor deposition chamber of claim 15 wherein the wafer temperature is substantially determined by the chuck temperature.

18. The physical vapor deposition chamber of claim 15 wherein the wafer and the target are disposed in a spaced-apart relation.

19. The physical vapor deposition chamber of claim 18 wherein the spaced-apart relation comprises about 45 mm.

20. The physical vapor deposition chamber of claim 15 further comprising a pedestal cover overlying the chuck, wherein the pedestal cover further comprises a plurality of pads on an upper surface thereof, and wherein the wafer is disposed on the plurality of pads.

21. The physical vapor deposition chamber of claim 15 wherein the material comprises aluminum or an aluminum alloy.

22. The physical vapor deposition chamber of claim 15 wherein the temperature range is between about 245° C. and 285° C.

23. The physical vapor deposition chamber of claim 15 wherein the controller determines a chuck temperature in a range of between about 350° C. and 450° C.

24. The physical vapor deposition chamber of claim 15 further comprising a temperature measuring device for determining the wafer temperature, wherein the controller is responsive to the wafer temperature for controlling the chuck heater in response thereto.

25. The physical vapor deposition chamber of claim 15 wherein the deposited material has a substantially <111> crystal orientation.

26. The physical vapor deposition chamber of claim 15 wherein the deposited material exhibits a desired grain orientation.
